(19) United States
(12) Patent Application Publication
(10) Pub. No.: US 2010/0123992 A1
(43) Pub. Date: May 20, 2010

(54) MULTI-STORAGE SYSTEM AND APPARATUS FOR PREVENTING INAPPROPRIATE REMOVAL IN MULTI-STORAGE SYSTEM AND METHOD THEREOF

(75) Inventor: Po-Hsueh Huang, Taipei City (TW)

Correspondence Address: J C PATENTS, 4 VENTURE, SUITE 250, IRVINE, CA, 92618, US

(73) Assignee: INVENTEC CORPORATION, Taipei City (TW)

(21) Appl. No.: 12/425,629

(22) Filed: Apr. 17, 2009

(30) Foreign Application Priority Data
Nov. 17, 2008 (TW) 97144387

(51) Int. Cl. G06F 1/16; H05K 5/00; G06F 12/00; H01H 9/28

(52) U.S. Cl. 361/269; 361/679.37; 711/114; 711/E12.001

(57) ABSTRACT

An apparatus for preventing inappropriate removal in a multi-storage system and a method thereof are provided. The apparatus includes a plurality of expending trays, a plurality of security devices, and a monitor unit. Storage devices are selectively installed in the expending trays. Each security device is disposed in a corresponding expending tray, and is used for locking the storage device installed therein. The monitor unit is used for detecting whether the installed storages have a redundant reliability. If the installed storages do not have the redundant reliability, the monitor unit activates the security units to lock a part of or all of the storage devices for preventing data accessing failure caused by inappropriate removal of the storage devices.

### CROSS-REFERENCE TO RELATED APPLICATION

This application claims the priority benefit of Taiwan application serial no. 97144387, filed Nov. 17, 2008. The entirety of the above-mentioned patent application is hereby incorporated by reference herein and made a part of specification.

### BACKGROUND OF THE INVENTION

1. Field of the Invention

The present invention relates to a multi-storage system. More particularly, the present invention relates to a multi-storage system and an apparatus for preventing inappropriate removal in the multi-storage system and a method thereof

2. Description of Related Art

In a field of computer, a computer server has a relatively high calculating capability, which can provide diversified function for simultaneous utilizations of different users. Therefore, a selection standard for hardware devices of the computer server is different from that of a general personal computer. The hardware devices of the computer server have to be capable of dealing a mass of loading, and have a relatively high usage lifespan, so as to avoid loss of data in the computer server due to damage of the hardware device during computing. Since a disk drive specifically used in the computer server is very expensive and has a limited storage space, most of the current disk drives of the computer server are redundant array of inexpensive disks (which is referred to as RAID hereinafter).

A basic concept of the RAID is to combine a plurality of general physical disk drives to form an array to function as one logical disk drive. The RAID logical disk drive is used for achieving objectives of a great volume and a convenient maintenance that cannot be implemented by the specific storage device of the computer server, and providing diversified combinations and corresponding functions thereof The RAID logical disk drive provides a hot swapping function, by which a single physical disk drive with hardware malfunction and damaged data can be directly removed, and a substituted physical disk drive can be installed for expanding or rebuilding.

Most of the physical disk drives of the current RAID logical disk drive are disposed in a disk carrier to connect a disk tray, and a mechanical lock is added between the disk carrier and the disk tray to prevent careless removal of the disk carrier. Since an operation of the mechanical lock is relied on human judgment, if a user is not familiar to the operation of such system and removes the physical disks in process of operation by mistake, data stored in the RAID logical disk drive may have irrecoverable error.

### SUMMARY OF THE INVENTION

The present invention is directed to a multi-storage system and an apparatus for preventing inappropriate removal in the multi-storage system and a method thereof, which is used for detecting an operation state of a plurality of storage devices in the multi-storage system to automatically determine whether to lock a part of or all of the storage devices to prevent irrecoverable error of data stored in the multi-storage system due to inappropriate removal of one or multiple storage devices.

The present invention is directed to a multi-storage system having an apparatus for preventing inappropriate removal in the multi-storage system, which can detect an operation state of a plurality of storage devices in the multi-storage system to automatically determine whether to lock a part of or all of the storage devices to prevent irrecoverable error of data stored in the multi-storage system due to inappropriate removal of one or multiple storage devices.

The present invention provides an apparatus for preventing inappropriate removal in a multi-storage system. The apparatus includes a storage unit and a monitor unit. The storage unit includes a plurality of expending trays and a plurality of security devices, wherein each of the expending trays is used for selectively installing storage devices, and each of the security devices is disposed in the corresponding expending tray. When the security device is enabled, the storage device installed in the corresponding expending tray cannot be removed; when the security device is disabled, the storage device installed in the corresponding expending tray can be removed. The monitor unit is coupled to the expending trays and the security devices, and is used for driving the storage devices installed in the expending trays, and detecting an operation state of the storage devices through the expending trays to determine whether the storage devices have a redundant reliability, and accordingly determine whether to control the security devices to lock a part of or all of the storage devices.

In an embodiment of the present invention, the security device is an electromagnetic lock.

In an embodiment of the present invention, the monitor unit includes a control unit and a management unit. The control unit is coupled to the expending trays, and is used for driving the storage devices installed in the expending trays and detecting the operation state of the storage devices through the expending trays. The management unit is coupled to the security devices and the control unit to obtain the operation state of the storage devices through the control unit, so as to determine whether the storage devices have the redundant reliability, and accordingly determine whether to control the security devices to lock a part of or all of the storage devices.

In an embodiment of the present invention, when the storage devices do not have the redundant reliability, the management unit enables the security devices to lock all of the storage devices.

In an embodiment of the present invention, when the storage devices have the redundant reliability, the management unit disables the security devices to unlock all of the storage devices.

In an embodiment of the present invention, when the management unit detects any of the storage devices is in a data rearrangement state, the management unit enables the security devices to lock all of the storage devices.

In an embodiment of the present invention, when the management unit detects that the storage device installed in the i-th expending tray is removed, the management unit disables the i-th security device corresponding to the i-th expending tray, and enables the other security devices to lock the other storage devices, wherein i is a positive integer.

The present invention provides a method for preventing inappropriate removal in a multi-storage system. The method can be described as follows. First, operation states of a plurality of storage devices in the multi-storage system are obtained. Next, whether the storage devices have a redundant reliability are determined according to the operation state of the storage devices, and when the storage devices do not have the redundant reliability, all of the storage devices are locked.

In an embodiment of the present invention, the method for preventing inappropriate removal in the multi-storage system further includes unlocking all of the storage devices when the storage devices have the redundant reliability.

In an embodiment of the present invention, the step of determining whether the storage devices have the redundant reliability according to the operation state of the storage devices includes obtaining the operation state of the storage devices to determine whether the operation state of the storage devices is RAID 1 or RAID 5, and locking all of the storage devices if the operation state of the storage devices is not RAID 1 or RAID 5.

In an embodiment of the present invention, the step of determining whether the storage devices have the redundant reliability according to the operation state of the storage devices further includes detecting whether any of the storage devices is in an expending state or a rebuilding state when the operation state of the storage devices is RAID 1 or RAID 5, and locking all of the storage devices when any of the storage devices is in the expending state or the rebuilding state.

In an embodiment of the present invention, the method for preventing inappropriate removal in the multi-storage system further includes unlocking all of the storage devices when there is no storage device being in the expending state or the rebuilding state.

In an embodiment of the present invention, the method for preventing inappropriate removal in the multi-storage system further includes detecting whether any of the storage devices is removed when there is no storage device being in the expending state or the rebuilding state, and locking the other storage devices when any of the storage devices is removed.

In an embodiment of the present invention, the method for preventing inappropriate removal in the multi-storage system further includes unlocking all of the storage devices when there is no storage device being removed.

In the present invention, the monitor unit detects the operation state of each of the expending tray to determine whether the operation state of the storage device installed in the corresponding expending tray has the redundant reliability. In some embodiments, the redundant reliability can include an expending state, a rebuilding state and a swapping state. The monitor unit detects whether the storage devices have the redundant reliability to determine whether to enable the corresponding security device to lock a part of or all of the storage devices, so as to prevent irrecoverable error of data stored in the multi-storage system due to inappropriate removal of one or multiple storage devices.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram illustrating an apparatus for preventing inappropriate removal according to an embodiment of the present invention.

FIGS. 2-4 are flowcharts illustrating methods for preventing inappropriate removal according to an embodiment of the present invention.

### DESCRIPTION OF EMBODIMENTS

In the following content, technique features of the present invention are described in detail for those with ordinary skill in the art.

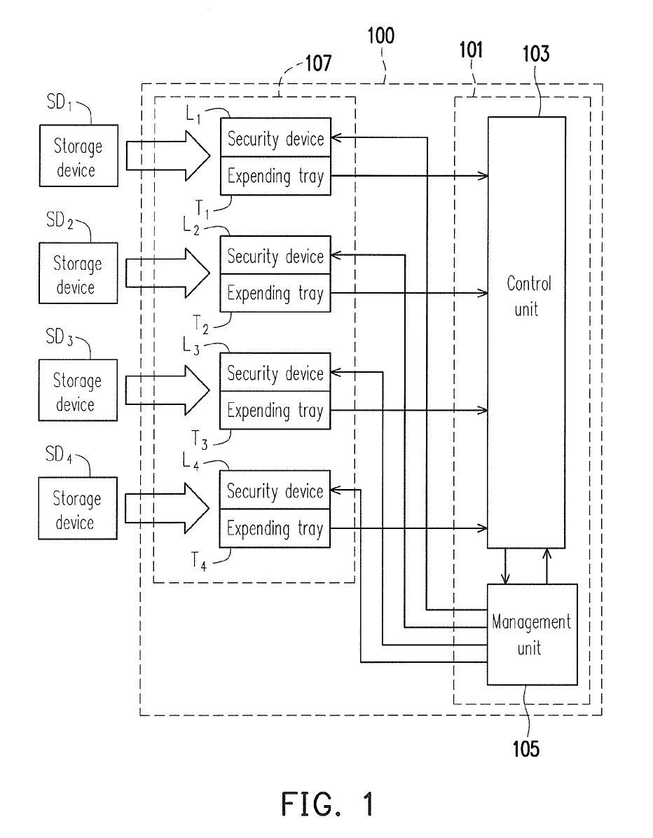

FIG. 1 is a schematic diagram illustrating an apparatus for preventing inappropriate removal according to an embodiment of the present invention. Referring to FIG. 1, apparatus for preventing inappropriate removal 100 at least includes a storage unit 107 and a monitor unit 101. The storage unit 107 at least includes expending trays T₁-T₄ and security devices L₁-L₄. Those skilled in the art can determine numbers of the expending tray and the security device according to actual requirements, and in the present embodiment, only the expending trays T₁-T₄ and the security devices L₁-L₄ are taken as an example. The expending trays T₁-T₄ are used for selectively installing storage devices, and the security devices L₁-L₄ are disposed in the corresponding expending trays T₁-T₄. In the present embodiment, the storage devices can be any type of physical disk drives, for example, hard disk drive (HDD), solid-state drive (SSD), etc.

When the security devices L₁-L₄ are enabled, and if the storage devices are installed in the corresponding expending trays T₁-T₄, the storage devices are locked and cannot be removed. When the security devices L₁-L₄ are disabled, the storage devices selectively installed in the corresponding expending trays T₁-T₄ can be removed. In the present embodiment, the security devices L₁-L₄ are electromagnetic locks, though the present invention is not limited thereto, and other lock devices, such as an electronic controlled block gate, etc. can also be applied. The security devices L₁-L₄ can lock the storage devices installed in the expending trays T₁-T₄ according to a received control signal, so as to prevent inappropriate removal of the storage devices. In some embodiment, a management unit 105 can enable the security devices L₁-L₄ to prevent the storage devices inserting into the expending trays T₁-T₄.

In the present embodiment, the monitor unit 101 at least includes a control unit 103 and a management unit 105. Wherein, the control unit 103 is coupled to the expending trays T₁-T₄. and is used for driving the storage devices selectively installed in the expending trays T₁-T₄, and detecting the operation state of the storage devices through the expending trays T₁-T₄. In the present embodiment, the control unit 103 is a RAID controller, though the present invention is not limited thereto, and a controller or a driver of any storage device array can also be applied. The management unit 105 is coupled to the control unit 103 and the security devices L₁-L₄. The management unit 105 obtains the operation state of the storage devices installed in the expending trays T₁-T₄ from the control unit 103, and determines whether the storage devices have a redundant reliability according to the operation state of the storage devices, so as to determine whether or not to enable or disable the security devices L₁-L₄ to lock a part of or all of the storage devices.

According to a RAID specification, the RAID logical disk drive has a plurality of implementing methods. In the present embodiment, the storage devices SD₁-SD₄ are physical disk drivers, and are sequentially installed in the expending trays T₁-T₄, though the present invention is not limited thereto, and different numbers of the storage device can also be applied according to the description of the present invention. The storage devices SD₁-SD₄ are defined as a logic magnetic domain, and data are dispersed in the storage devices SD₁-SD₄. Definition of the redundant reliability is as follows. Whether the same data recorded in the storage devices SD₁-SD₄ installed in the storage unit 107 is correspondingly stored at different storage devices SD₁-SD₄ is determined, and if yes, the storage devices SD₁-SD₄ are defined to have the redundant reliability.

For example, the implementing methods of the RAID include RAID level 0 (referred to as RAID 0 hereinafter), RAIL level 1 (referred to as RAID 1 herein after) and RAID level 5 (referred to as RAID 5), etc. Those skilled in the art should understand that the operation methods of the RAID logical disk drive and the implementing methods of the RAID further include RAID level 2, RAID level 3, . . . , etc. Therefore, only the part related to the present embodiment is described below. Though only the aforementioned implementing method of the RAID is taken as an example, the present invention is not limited thereto, and other implementing methods of the RAID can also be applied.

The control unit 103 obtains the operation state of the storage devices SD₁-SD₄ through the expending trays T₁-T₄, and the management unit 105 sends a request to the control unit 103 to obtain the operation state of the storage devices SD₁-SD₄. Here, assuming the multi-storage system of FIG. 1 is set to the RAID 0. Therefore, the control unit 103 responses the above request and notifies the management unit 105 that the operation state of the storage devices SD₁-SD₄ within the expending trays T₁-T₄ is the RAID 0. Since the RAID 0 logical disk drive does not have the redundant reliability, during the operation of the RAID 0 logical disk drive, if any of the storage devices (for example, the storage device SD₁) is removed, data stored in the RAID 0 logical disk drive may have an irrecoverable error. Therefore, when the corresponding storage devices SD₁-SD₄ in the expending trays T₁-T₄ do not have the redundant reliability, the control unit 103 enables the security devices L₁-L₄ to lock the storage devices SD₁-SD₄ installed in the expending trays T₁-T₄ to prevent inappropriate removal.

Assuming the multi-storage system of FIG. 1 is set to the RAID 1 or the RAID 5. When the management unit 105 detects the operation state of the storage devices SD₁-SD₄ installed in the expending trays T₁-T₄ is the RAID 1 or the RAID 5 through the control unit 103, since the RAID 1 or the RAID 5 logical disk drive has the redundant reliability, the management unit 105 disables all of the security devices L₁-L₄. Now, the storage devices SD₁-SD₄ installed in the expending trays T₁-T₄ are unlocked and are available for being removed.

When a storage space of the RAID 1 or the RAID 5 logical disk drive is inadequate, new physical disk drives can be added to expend the storage space. Alternatively, when any of the physical disk drive is malfunctioned, the malfunctioned physical disk drive can be substitute by a normal physical disk drive to rebuild the data. In the present embodiment, when the management unit 105 detects the operation state of the storage device SD₁ (not limited to the storage device SD₁) in the RAID1 or RAID 5 logic disk drive is in an expending state or a rebuilding (data rearrangement) state via the control unit 103, the RAID1 or RAID 5 logic disk drive is regarded not having the redundant reliability. In this case, none of the storage devices SD₁-SD₄ can be removed. Therefore, the management unit 105 enables the security devices L₁-L₄ to prevent removal of the storage devices SD₁-SD₄ installed in the expending trays T₁-T₄.

Moreover, since the RAID 1 or the RAID 5 has the redundant reliability, namely, one of the physical disk drives forming the RAID 1 or the RAID 5 is allowed to have an error or to be malfunctioned, and since most of the current physical disk drives are disk drives having a serial attached SCSI (SAS) specification or a serial advanced technology attachment (SATA) specification (which can support a hot swapping operation), if one of the physical disk drive has the error or is malfunctioned, it can be removed for inspection or can be substituted by the other physical disk drive. When any of the storage devices in the RAID 1 or the RAID 5 logical disk drive is removed, the remained RAID 1 or RAID 5 is also regarded to not have the redundant reliability, since if the error or the malfunction of the physical disk drive is again occurred, or the physical disk drive is removed, it is out of an allowed redundancy.

When the RAID 1 or the RAID 5 logical disk drive has the redundant reliability, the management unit 105 disables the security devices L₁-L₄ to allow removal of the storage devices SD₁-SD₄ installed in the expending trays T₁-T₄. If the storage device SD₁ (which is not limited to the storage device SD₁, and can also be any of the storage devices SD₁-SD₄) is now removed, and the management unit 105 detects the removal of the storage device SD₁ via the control unit 103, the management unit 105 disables the security device L₁, so that the other storage device is allowed to be installed in the expending tray T₁. Now, since the RAID 1 or RAID 5 logical disk drive does not have the redundant reliability, the management unit 105 enables the other security devices L₂-L₄ to prevent removal of the storage devices SD₂-SD₄ in the expending trays T₂-T₄.

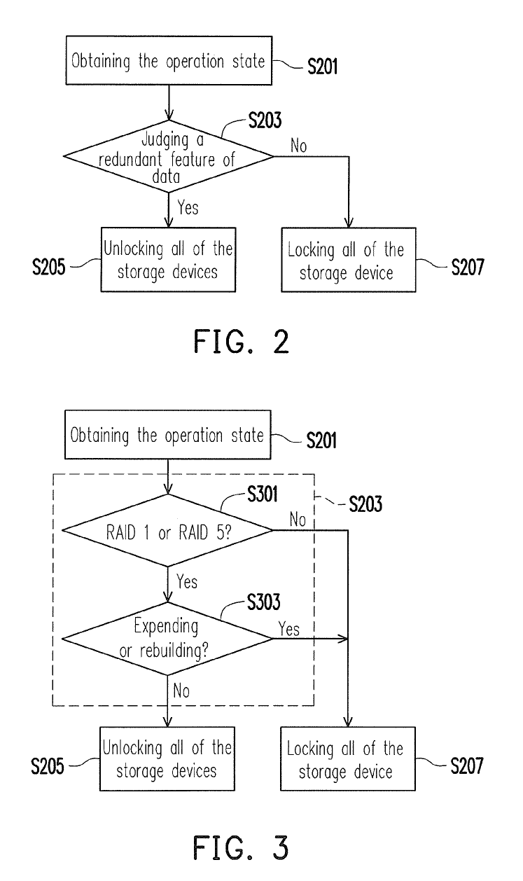

According to the above description, a method for preventing inappropriate removal in a multi-storage system is provided for those skilled in the art. FIG. 2 is a flowchart illustrating a method for preventing inappropriate removal according to an embodiment of the present invention. Referring to FIG. 2, first, in step S201, the operation state of the storage devices in the multi-storage system is obtained. Next, in step S203, whether the storage devices have the redundant reliability is determined according to the operation state of the storage devices. If the storage devices do not have the redundant reliability (RAID 0), all of the storage devices are locked to prevent inappropriate removal (step S207). Otherwise, in step S205, if the storage devices have the redundant reliability, all of the storage devices are unlocked. Those skilled in the art can implement the steps S205 and S207 by any method. For example, the security devices L₁-L₄ of FIG. 1 can be applied to lock (or unlock) all of the storage devices, and detailed description thereof is not repeated.

The step S203 can be implemented according to a following method. Referring to FIG. 3, first, the operation state of the storage devices is obtained (step S201). Next, whether the operation state of the storage devices is the RAID 1 or the RAID 5 is determined (step S301). If the operation state of the storage devices is not the RAID 1 or the RAID 5 (i.e. the storage devices do not have the redundant reliability), all of the storage devices are locked to prevent the inappropriate removal. If the operation state of the storage devices is the RAID 1 or the RAID 5, whether any of the storage devices is in the expending state or the rebuilding state is detected (step S303). If there is one storage device is in the expending state or the rebuilding state, all of the storage devices are then locked to prevent the inappropriate removal (step S207). If all of the storage devices are not in the expending state or the rebuilding state, the storage devices are then unlocked (step S205).

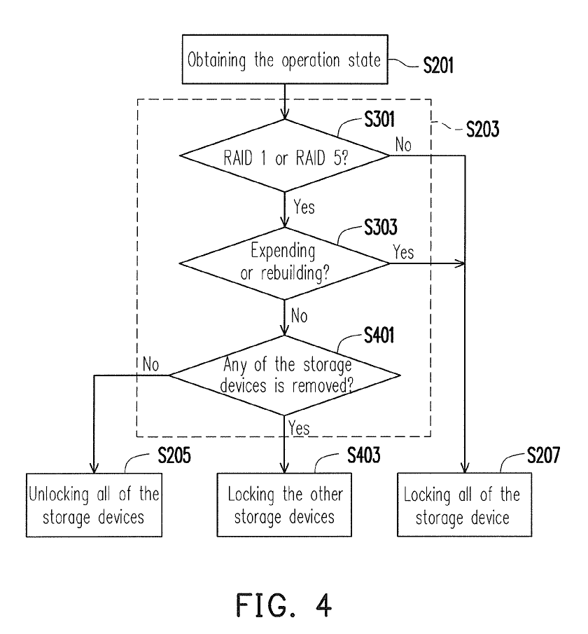

FIG. 4 is a flowchart illustrating a method for preventing inappropriate removal according to an embodiment of the present invention. A part of steps of FIG. 4 are the same to that of FIG. 3, and therefore detailed description thereof is not repeated. Referring to FIG. 4, in the method of the present embodiment, the step S203 can also be as follows. After the steps 301 and 303, if all of the storage devices are not in the expending state or the rebuilding state, whether any of the storage devices is removed is detected (step S401). If one of the storage devices is detected to be removed (now, the other storage devices do not have the redundant reliability), the other devices are then locked (step S403). If there is no storage device being removed, all of the storage devices are then unlocked (step S205).

In the aforementioned embodiment, the monitor unit 101 is used for detecting the operation state of the storage devices SD₁-SD₄ to determine whether the storage devices SD₁-SD₄ have the redundant reliability, and determine whether or not to enable the corresponding security devices L₁-L₄ to lock a part of or all of the storage devices SD₁-SD₄. When the monitor unit 101 enables any of the security devices (for example, the security device L₁), the storage device (for example, the storage device SD₁) installed in the corresponding expending tray (for example, the expending tray T₁) is then locked by the security device L₁, so that the storage device SD₁ cannot be removed, so as to prevent irrecoverable error of data stored in the multi-storage system due to inappropriate removal of one or multiple storage devices.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An apparatus for preventing inappropriate removal in a multi-storage system, comprising:
a storage unit, comprising:
a plurality of expending trays, selectively installing a plurality of storage devices; and
a plurality of security devices, each of the security devices being disposed in the corresponding expending tray, wherein when the security device is enabled, the storage device installed in the corresponding expending tray cannot be removed, and when the security device is disabled, the storage device installed in the corresponding expending tray can be removed; and
a monitor unit, coupled to the expending trays and the security devices for driving the storage devices installed in the expending trays, and detecting an operation state of the storage devices through the expending trays to determine whether the storage devices have a redundant reliability, and accordingly determine whether to control the security devices to lock a part of or all of the storage devices.

2. The apparatus for preventing inappropriate removal in a multi-storage system as claimed in claim 1, wherein the security device is an electromagnetic lock.

3. The apparatus for preventing inappropriate removal in a multi-storage system as claimed in claim 1, wherein the monitor unit comprises:
a control unit, coupled to the expending trays, for driving the storage devices installed in the expending trays and detecting the operation state of the storage devices through the expending trays; and
a management unit, coupled to the security devices and the control unit to determine whether the storage devices have the redundant reliability by obtaining the operation state of the storage devices through the control unit, and accordingly determine whether to control the security devices to lock a part of or all of the storage devices.

4. The apparatus for preventing inappropriate removal in a multi-storage system as claimed in claim 3, wherein the management unit enables the security devices to lock all of the storage devices when the storage devices do not have the redundant reliability, and the management unit disables the security devices to unlock all of the storage devices when the storage devices have the redundant reliability.

5. The apparatus for preventing inappropriate removal in a multi-storage system as claimed in claim 3, wherein when the management unit detects any one of the storage devices is in a data rearrangement state, the management unit enables the security devices to lock all of the storage devices.

6. The apparatus for preventing inappropriate removal in a multi-storage system as claimed in claim 5, wherein the data rearrangement state is a rebuilding state or an expending state.

7. The apparatus for preventing inappropriate removal in a multi-storage system as claimed in claim 3, wherein when the management unit detects that the storage device installed in the i-th expending tray is removed, the management unit disables the i-th security device corresponding to the i-th expending tray, and enables the other security devices to lock the other storage devices, wherein i is a positive integer.

8. A multi-storage system, comprising:
a plurality of storage devices;
a plurality of expending trays, selectively installing the corresponding storage devices;
a plurality of security devices, each of the security devices being disposed in the corresponding expending tray, wherein when the security device is enabled, the storage device installed in the corresponding expending tray cannot be removed, and when the security device is disabled, the storage device installed in the corresponding expending tray can be removed; and
a monitor unit, coupled to the expending trays and the security devices for driving the storage devices installed in the expending trays, and detecting an operation state of the storage devices through the expending trays to determine whether the storage devices have a redundant reliability, and accordingly determine whether to control the security devices to lock a part of or all of the storage devices.

9. The multi-storage system as claimed in claim 8, wherein the security device is an electromagnetic lock.

10. The multi-storage system as claimed in claim 8, wherein the monitor unit comprises:
a control unit, coupled to the expending trays, for driving the storage devices installed in the expending trays and detecting the operation state of the storage devices through the expending trays; and
a management unit, coupled to the security devices and the control unit to determine whether the storage devices have the redundant reliability by obtaining the operation state of the storage devices through the control unit, and accordingly determine whether to control the security devices to lock a part of or all of the storage devices.

11. The multi-storage system as claimed in claim 10, wherein the management unit enables the security devices to lock all of the storage devices when the storage devices do not have the redundant reliability, and the management unit disables the security devices to unlock all of the storage devices when the storage devices have the redundant reliability.

12. The multi-storage system as claimed in claim 11, wherein when the management unit detects any one of the storage devices is in a data rearrangement state, the management unit enables the security devices to lock all of the storage devices.

13. The multi-storage system as claimed in claim 11, wherein when the management unit detects that the storage device installed in the i-th expending tray is removed, the management unit disables the i-th security device corresponding to the i-th expending tray, and enables the other security devices to lock the other storage devices, wherein i is a positive integer.

14. The multi-storage system as claimed in claim 10, wherein the control unit is a RAID controller.

15. A method for preventing inappropriate removal in a multi-storage system, comprising:
a. obtaining an operation state of a plurality of storage devices in the multi-storage system;
b. determining whether the storage devices have a redundant reliability according to the operation state of the storage devices; and
c. locking all of the storage devices when the storage devices do not have the redundant reliability.

16. The method for preventing inappropriate removal in a multi-storage system as claimed in claim 15 further comprising:
unlocking all of the storage devices when the storage devices have the redundant reliability.

17. The method for preventing inappropriate removal in a multi-storage system as claimed in claim 15, wherein the step b comprises:
obtaining the operation state of the storage devices to determine whether the operation state of the storage devices is RAID 1 or RAID 5;
locking all of the storage devices if the operation state of the storage devices is not RAID 1 or RAID 5;
detecting whether any of the storage devices is in an expending state or a rebuilding state when the operation state of the storage devices is RAID 1 or RAID 5; and
locking all of the storage devices when any of the storage devices is in the expending state or the rebuilding state.

18. The method for preventing inappropriate removal in a multi-storage system as claimed in claim 17 further comprising:
unlocking all of the storage devices when there is no storage device being in the expending state or the rebuilding state.

19. The method for preventing inappropriate removal in a multi-storage system as claimed in claim 17, wherein the step b further comprises:
detecting whether any of the storage devices is removed when there is no storage device being in the expending state or the rebuilding state; and
locking the other storage devices when any of the storage devices is removed.

20. The method for preventing inappropriate removal in a multi-storage system as claimed in claim 19 further comprising:
unlocking all of the storage devices when there is no storage device being removed.
